(19) United States
(12) Patent Application Publication
(10) Pub. No.: US 2026/0084954 A1
(43) Pub. Date: Mar. 26, 2026

(54) MULTIDIMENSIONAL CANTILEVERS AND STRESS-PROGRAMMABLE OUT-OF-PLANE INTERPOSERS FOR 3-D PHOTONIC INTEGRATION AND CONTROL

(71) Applicant: The MITRE Corporation, McLean, VA (US)

(72) Inventor: Henry WEN, Reading, MA (US)

(73) Assignee: The MITRE Corporation, McLean, VA (US)

(21) Appl. No.: 19/094,348

(22) Filed: Mar. 28, 2025

Related U.S. Application Data
(60) Provisional application No. 63/697,893, filed on Sep. 23, 2024.

(51) Int. Cl. B81B 3/00; B81C 1/00; G02B 26/10

(52) U.S. Cl. CPC B81B 3/0043; B81C 1/0015; G02B 26/101; G02B 26/103; B81B 2203/0118; B81B 2203/04; B81C 2201/0105; B81C 2201/0133

(57) ABSTRACT

A cantilever comprises a first dielectric layer, wherein the first dielectric layer has a first intrinsic stress, and a second dielectric layer overlying the first dielectric layer, wherein the second dielectric layer has a second intrinsic stress that is different than the first intrinsic stress. The cantilever is curved along a lengthwise z-dimension of the cantilever due to a difference between the first and second intrinsic stresses. The second dielectric layer comprises a plurality of crossbars angled relative to an x-dimension width of the cantilever to control curvature in the x-dimension width of the cantilever, to induce a change in pitch along the length of the cantilever, and to induce a change in roll along the length of the cantilever.

### CROSS-REFERENCE TO RELATED APPLICATIONS

This application claims the benefit of U.S. Provisional Application No. 63/697,893 filed Sep. 23, 2024, the entire contents of which are incorporated herein by reference.

### FIELD

The present disclosure relates generally to micro-mechanical and nano-mechanical cantilevers for use in microelectromechanical systems (MEMS), photonic devices, micro-robotic devices, and the like.

### BACKGROUND

The scalability of a micron-scale or nano-scale system is often restricted by an inability to effectively interconnect system components without compromising important system characteristics (e.g., size or efficiency). For example, the scalability of a photonic integrated circuit may be limited by an inability to perform crucial functions such as the steerable projection and collection of optical modes between the circuit and a set of targets in free space without using devices that have relatively large footprints (e.g., MEMs mirrors) or devices that are challenging to integrate (e.g., optical phase arrays). These challenges can hamper the development of technologies that can be formed from networks of micron-scale and nano-scale devices.

Integrated opto-electronic platforms are effectively 2D due to the planar nature of the underlying lithographic fabrication processes. Achieving and controlling the out-of-plane deflection of mechanical, electrical, and photonic components can enable a wide range of applications including beam scanning, 2.5, and 3-D opto-electronic integration, and optomechanical sensing and manipulation across multiple scientific and technological domains.

For photonically-enabled computing platforms breaking the planar interface constraint and interconnecting multiple dies into a unified whole is crucial to reach the component density and connectivity required for commercial utility.

A wide variety of automated techniques for 3D nanofabrication have been attempted, including kirigami/origami structures generated via various stress or chemical engineering efforts (S. Chen, J. Chen, X. Zhang, Z.-Y. Li, and J. Li, “Kirigami/origami: unfolding the new regime of advanced 3D microfabrication/nanofabrication with “folding.”” Light: Science & Applications 9, 1-19 (2020)). However, many of these are either passive structures upon release, not scalable, or not compatible with cryogenic temperatures or CMOS platforms.

### SUMMARY

Described are micron-scale and nano-scale curving or curling cantilever structures for use in a wide range of applications, including as components of photonic and electronic integrated circuits. The provided cantilevers can be fabricated using wafer-scale fabrication techniques and materials (e.g., CMOS fabrication techniques and materials) and can comprise a stack of dielectric layers having differing intrinsic stress values. When a cantilever is released from its underlying substrate during fabrication, the non-zero stress gradient across its constituent dielectric layers causes the cantilever to deflect and curve along its length.

The topmost dielectric layer (relative to the substrate to which the cantilever is anchored) of a cantilever can be geometrically configured to amplify the cantilever's deflection along its length. Etching the topmost dielectric layer into a plurality of crossbars, for example, can redirect lateral stress (e.g., stress along the width of the cantilever) in the cantilever along the cantilever's length to increase the deflection of the cantilever along its length. Varying properties of the crossbar pattern such as the crossbar duty cycle can program the curvature of the cantilever and, in some embodiments, can enable to cantilever to assume complex geometric structures once released from the underlying substrate.

The curving of a cantilever can be passive or can be actively controlled. A passive curving cantilever may permanently assume a curved shape after being released from the underlying substrate. Actively controlled curving cantilevers, on the other hand, can be moved as needed between two or more curvature states, e.g., via piezoelectric actuation. For example, an active curving cantilever may be configured to be moved between an undeflected state and a deflected state.

The provided cantilevers can be implemented as optical interconnects in optical systems such as photonic integrated circuits (PICs) by patterning a waveguide channel within the topmost cantilever layer and can enable crucial functionalities such as the steerable projection and collection of multiple optical modes between a PIC and a set of targets in free space. Active curving cantilevers (e.g., piezoelectrically actuated cantilevers) in particular can enable, e.g., two-dimensional beam scanning from anywhere on a photonic chip over a large number of diffraction limited spots in the far field. Advantageously, unlike beam scanning approaches that rely on reflective scanners, integrated optical phase arrays, or scanning fibers, the disclosed cantilevers are highly scalable and have small footprints (e.g., less than 1 mm²), wide fields-of-view, and broadband outputs. As a result, the provided cantilevers can facilitate the creation of complex optical systems such as quantum computers.

Out-of-plane photonic NEMS-PIC “ski-jump” curling cantilevers, recently demonstrated on a wafer-scale cryo-compatible CMOS platform as 2D beam scanners for display and atomic control, can also serve as the basis for non-planar off-chip photonic I/O (M. Saha, A. S. Greenspon, Y. H. Wen, M. Zimmermann, A. Leenheer, M. Dong, G. Clark, G. Gilbert, M. Eichenfield, and D. R. Englund, “High-speed off-chip beam steering via photonic integrated waveguides embedded on vertical ski-jump cantilevers,” Frontiers in Optics+Laser Science 2023 (FiO, LS) (2023)). The out-of-plane deflection of these devices was achieved by engineering the directionality of the stress gradient across the cantilever film stack to induce static curling along the length of the cantilever, i.e. control of the “pitch” degree of freedom.

Here, we disclose improved systems and methods that achieve control of the “roll” degree of freedom. The combination of pitch and roll gives the ability to fully program the shape of the cantilever within the 3D volume above the chip surface limited only by the inherent stresses of the thin films.

In some embodiments, a cantilever is provided comprising: a first dielectric layer, wherein the first dielectric layer has a first intrinsic stress; a second dielectric layer overlying the first dielectric layer, wherein the second dielectric layer has a second intrinsic stress that is different than the first intrinsic stress, wherein the cantilever is curved along a lengthwise z-dimension of the cantilever due to a difference between the first and second intrinsic stresses, and wherein the second dielectric layer comprises a plurality of crossbars angled relative to an x-dimension width of the cantilever to control curvature in the x-dimension width of the cantilever, to induce a change in pitch along the length of the cantilever, and to induce a change in roll along the length of the cantilever.

In some embodiments, all crossbars of the plurality of crossbars are oriented at a first non-orthogonal angle relative to the width of the cantilever, such that the change in roll along the length of the cantilever is monotonic.

In some embodiments, all crossbars of the plurality of crossbars have a regular periodic spacing with respect to one another, such that the roll along the length of the cantilever has a constant rate of change with respect to lengthwise position along the cantilever.

In some embodiments, a first crossbar of the plurality of crossbars is oriented at a first non-orthogonal angle relative to the width of the cantilever, and a second crossbar of the plurality of crossbars is oriented at a second non-orthogonal angle relative to the width of the cantilever, the first non-orthogonal angle is different from the second non-orthogonal angle.

In some embodiments, the first non-orthogonal angle and the second non-orthogonal angle are both angled in a common direction with respect to the width of the cantilever, such that the change in roll along the length of the cantilever is monotonic, and such that the roll along the length of the cantilever has a varying rate of change with respect to lengthwise position along the cantilever.

In some embodiments, the first non-orthogonal angle and the second non-orthogonal are angled in different directions with respect to the width of the cantilever, such that the change in roll along the length of the cantilever is non-monotonic.

In some embodiments, the cantilever comprises a piezoelectric layer disposed between the first layer and the second layer.

In some embodiments, the cantilever comprises one or more waveguides.

In some embodiments, a cantilever is provided comprising: a first dielectric layer, wherein the first dielectric layer has a first intrinsic stress; a second dielectric layer overlying the first dielectric layer, wherein the second dielectric layer has a second intrinsic stress that is different than the first intrinsic stress, wherein the cantilever is curved along a lengthwise z-dimension of the cantilever due to a difference between the first and second intrinsic stresses, and wherein the second dielectric layer varies in thickness along a length of the cantilever and along an x-dimension width of the cantilever, such that the varying thickness controls curvature in one or more dimensions of the cantilever.

In some embodiments, the second dielectric layer comprises a pattern of troughs formed in the second dielectric layer that varies along the length and in the x-dimension width.

In some embodiments, a change in roll along the length of the cantilever is monotonic.

In some embodiments, the roll along the length of the cantilever has a constant rate of change with respect to lengthwise position along the cantilever.

In some embodiments, the roll along the length of the cantilever has a varying rate of change with respect to lengthwise position along the cantilever.

In some embodiments, the change in roll along the length of the cantilever is non-monotonic.

In some embodiments, the cantilever comprises a piezoelectric layer disposed between the first layer and the second layer.

In some embodiments, the cantilever comprises one or more waveguides.

In some embodiments, a photonic system is provided comprising a photonic integrated circuit (PIC) chip comprising any cantilever described herein.

Any one or more features from any of the above embodiments may be combined, in whole or in part, with all or part of any of the other embodiments and/or with all or part of any other disclosure herein.

### BRIEF DESCRIPTION OF THE DRA WINGS

The invention will now be described, by way of example only, with reference to the accompanying drawings, in which:

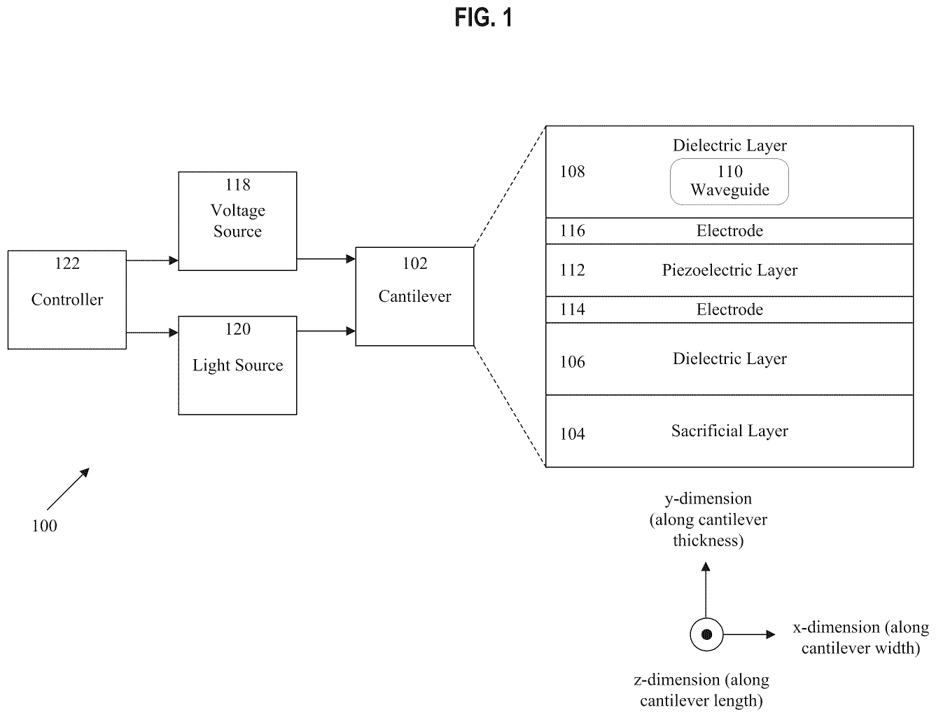

FIG. 1 illustrates a photonic system with an active curving cantilever (e.g., piezoelectrically actuated cantilever) patterned with crossbars, according to some embodiments.

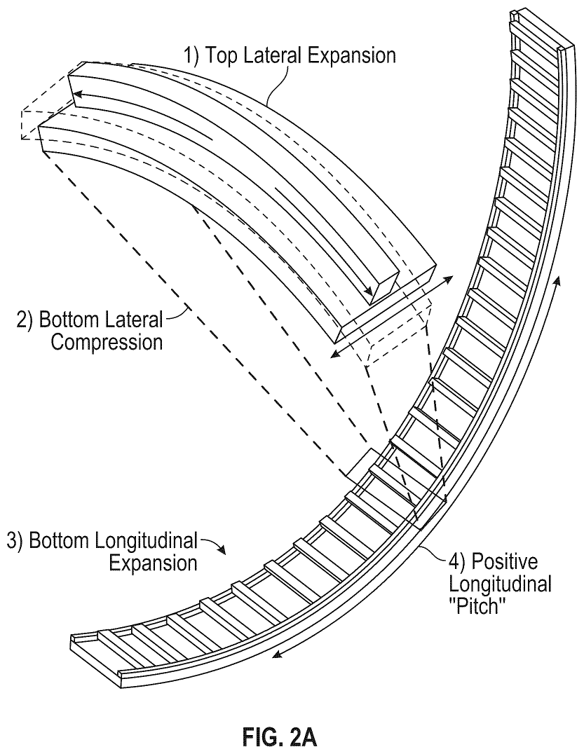

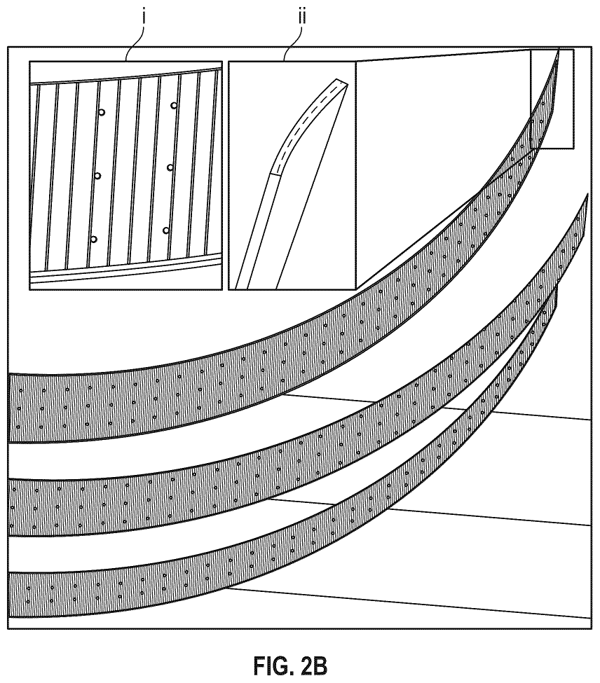

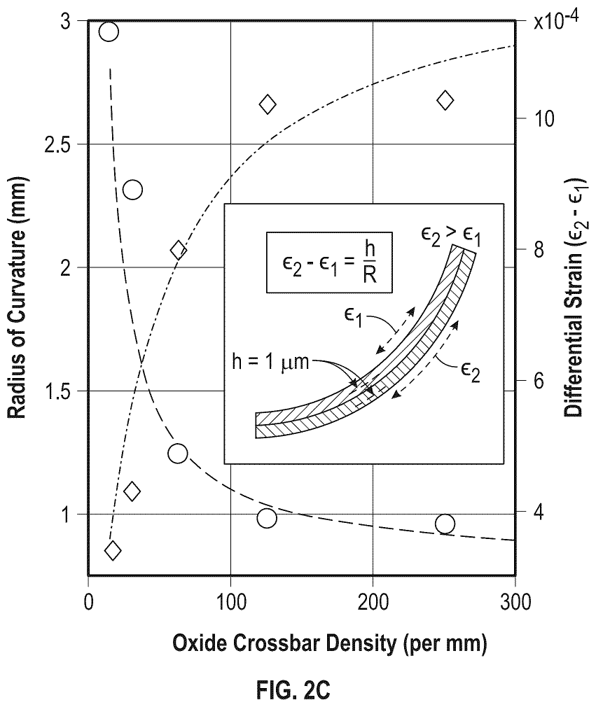

FIG. 2A illustrates crossbar patterning on a cantilever and stress engineering of the crossbar patterning, according to some embodiments.

FIG. 2B illustrates example cantilevers curled upwards, in which each example cantilever has a different period, T, of the crossbar patterning, according to some embodiments.

FIG. 2C is a plot of radius of curvature versus oxide crossbar density and differential strain versus oxide crossbar density, according to some embodiments.

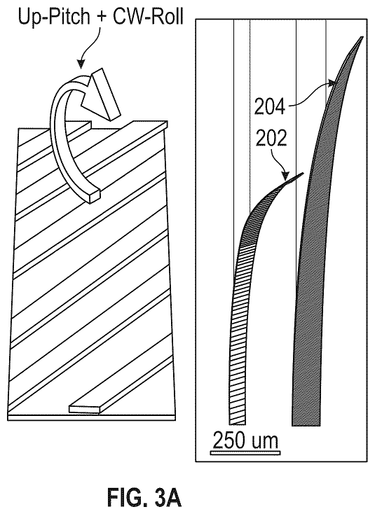

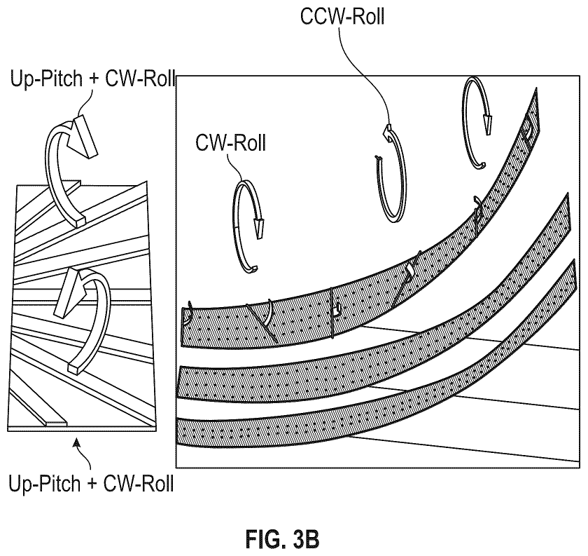

FIG. 3A illustrates an exemplary crossbar patterning that varies the pitch and roll of cantilevers, in which the crossbars on the cantilevers are patterned with ribs that are angled counterclockwise from a horizontal dimension of a cantilever, according to some embodiments.

FIG. 3B illustrates an exemplary crossbar patterning that varies the pitch and roll of cantilevers, in which the crossbars on the cantilevers are patterned with angles counterclockwise and clockwise from a horizontal dimension of the cantilevers, according to some embodiments.

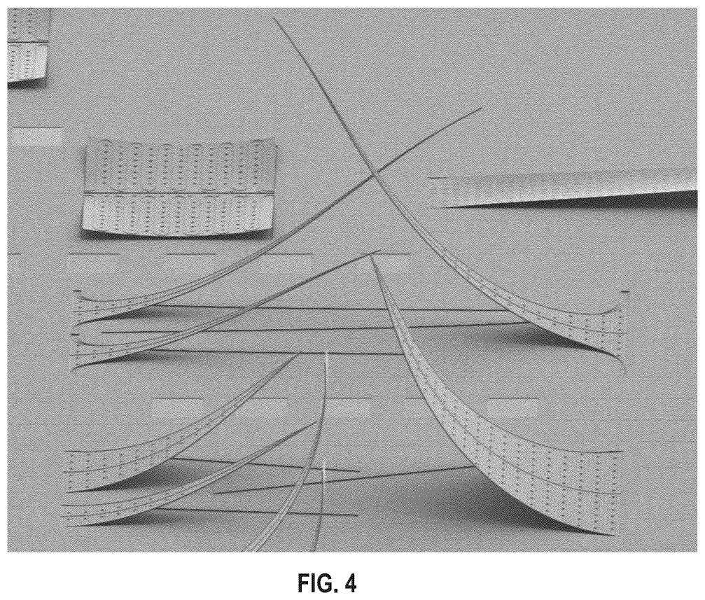

FIG. 4 illustrates pitch and roll of cantilevers with various (and/or varying) widths and crossbar patterning, according to some embodiments.

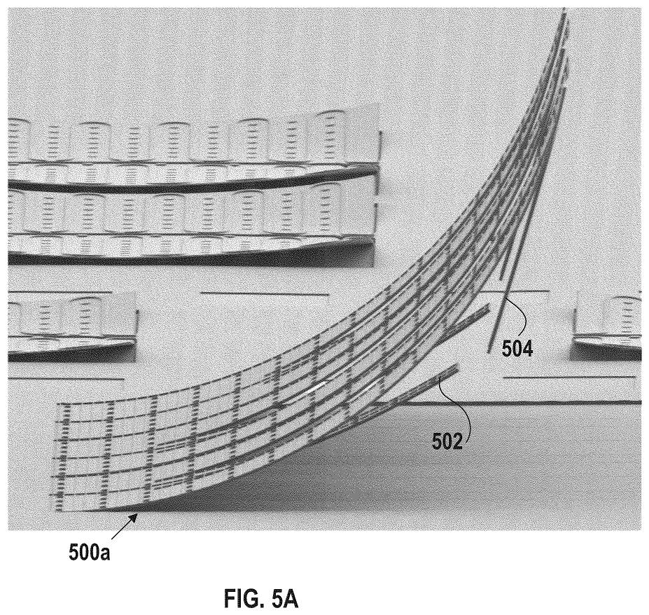

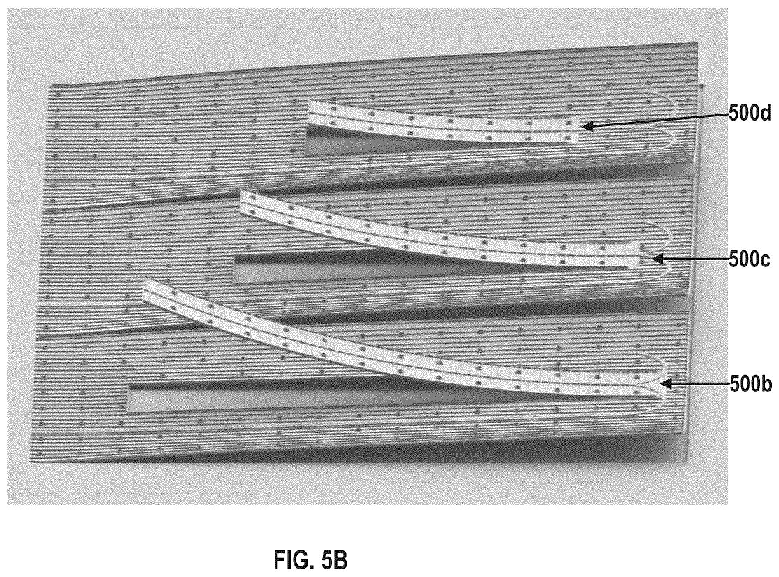

FIG. 5A illustrates a compound structure formed from a plurality of cantilevers with crossbar patterning, according to some embodiments.

FIG. 5B illustrates three compound structures, each formed from a plurality of cantilevers with crossbar patterning, and each compound structure exhibiting a different pitch and roll, according to some embodiments.

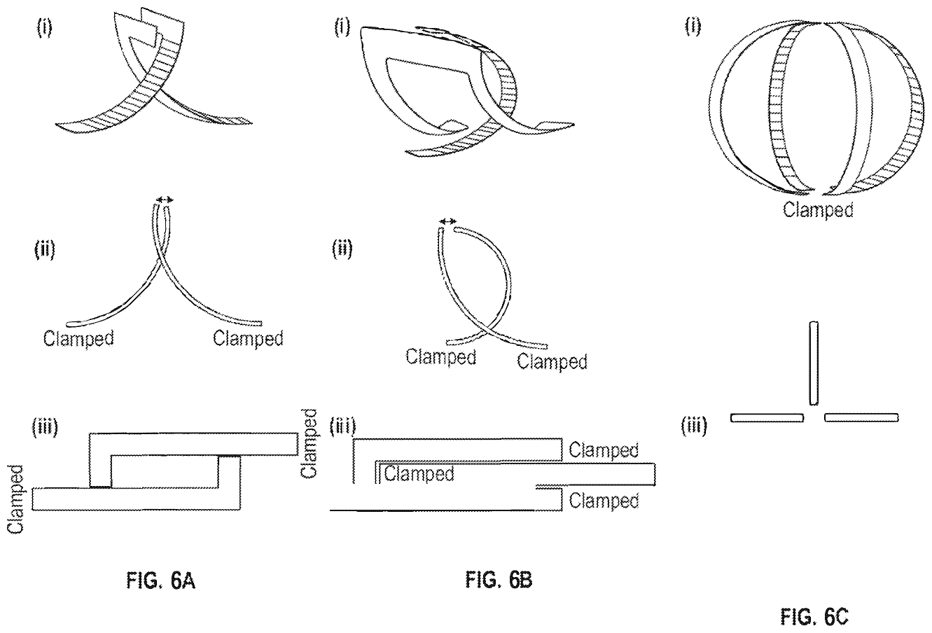

FIG. 6A illustrates a gripping actuator for a micro-robotic system, according to some embodiments.

FIG. 6B illustrates a gripping actuator for a micro-robotic system, according to some embodiments.

FIG. 6C illustrates a gripping actuator for a micro-robotic system, according to some embodiments.

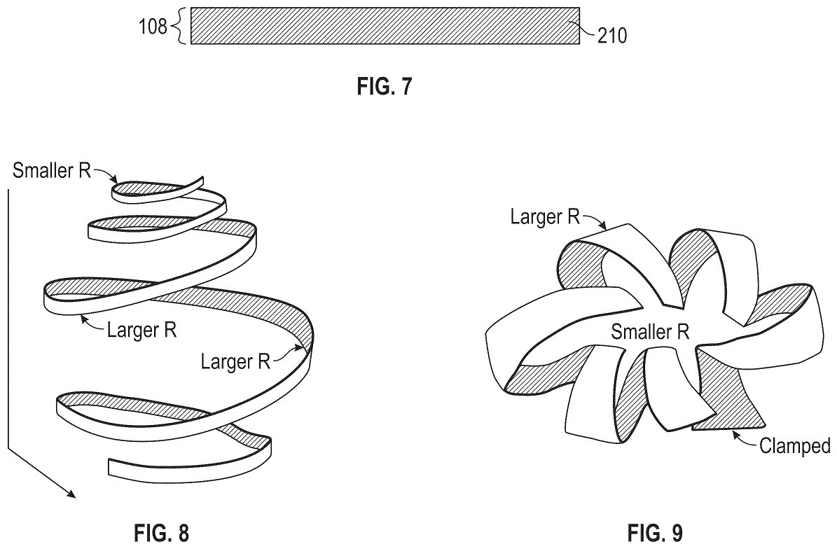

FIG. 7 illustrates an example of a crossbar pattern for creating helical structures, according to some embodiments.

FIG. 8 illustrates an example of a ball-shaped structure, according to some embodiments.

FIG. 9 illustrates an example of a toroidal structure, according to some embodiments.

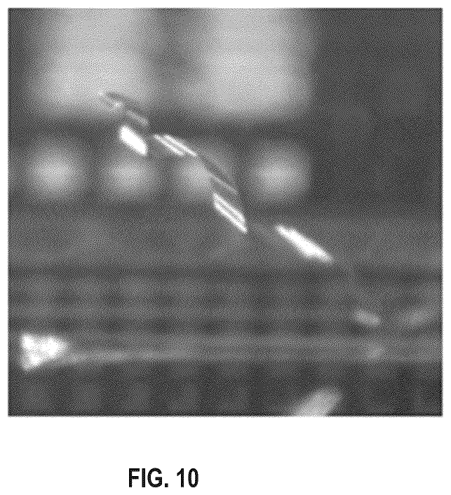

FIG. 10 is an image of a cantilever in a helical structure, according to some embodiments.

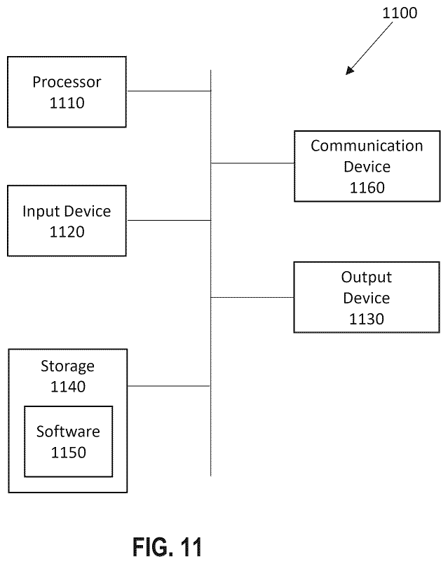

FIG. 11 illustrates a computing unit, according to some embodiments.

### DETAILED DESCRIPTION

Described are micron-scale and nano-scale curving or curling cantilever structures and devices and systems including such structures for use in a wide range of applications. For example, described are cantilever structures that can be used as components of photonic and electronic integrated circuits. The provided cantilevers can be fabricated using wafer-scale fabrication techniques and materials (e.g., conventional CMOS fabrication techniques and materials). An exemplary cantilever can comprise a stack of dielectric layers having differing intrinsic stress values. When the cantilever is released from its underlying substrate during fabrication, the non-zero stress gradient across its constituent dielectric layers causes the cantilever to deflect and curve along its length.

The topmost dielectric layer (relative to the substrate to which the cantilever is anchored) of a cantilever can be geometrically configured to amplify the cantilever's deflection along its length. Etching the topmost dielectric layer into a plurality of crossbars, for example, can redirect lateral stress (e.g., stress along the width of the cantilever) in the cantilever along the cantilever's length to increase the deflection of the cantilever along its length. Varying properties of the crossbar pattern such as the crossbar duty cycle can program the curvature of the cantilever and, in some embodiments, can enable to cantilever to assume complex geometric structures once released from the underlying substrate.

The curving of a cantilever can be passive or can be actively controlled. A passive curving cantilever may permanently assume a curved shape after being released from the underlying substrate. Actively controlled curving cantilevers, on the other hand, can be moved as needed between two or more curvature states, e.g., via piezoelectric actuation. For example, an active curving cantilever may be configured to be moved between an undeflected state and a deflected state.

The provided cantilevers can be implemented as optical interconnects in optical systems such as photonic integrated circuits (PICs) by patterning a waveguide channel within the topmost cantilever layer and can enable crucial functionalities such as the steerable projection and collection of multiple optical modes between a PIC and a set of targets in free space. Active curving cantilevers (e.g., piezoelectrically actuated cantilevers) in particular can enable, e.g., two-dimensional beam scanning from anywhere on a photonic chip over a large number of diffraction limited spots in the far field. Advantageously, unlike beam scanning approaches that rely on reflective scanners, integrated optical phase arrays, or scanning fibers, the disclosed cantilevers are highly scalable and have small footprints (e.g., less than 1 mm²), wide fields-of-view, and broadband outputs. As a result, the provided cantilevers can facilitate the creation of complex optical systems such as quantum computers.

According to various embodiments, cantilevers configured according to the principles described herein are used in micro- and nano-electromechanical systems (MEMs and NEMs), micro- and nano-scale robotics, and self-assembling micro- and nano-scale structures.

As used herein, cantilever dimensions may be referred to with respect to an x-direction (or x-dimension), a y-direction (or y-dimension), and a z-direction (or z-dimension). This Cartesian convention may be defined with respect to the tip of an active curving cantilever, and may also be used to refer to an imaging plane onto which a light beam from the cantilever projects. The positive z-direction may be the direction in which light travels in the waveguide along the length of the cantilever, the direction along which light projects from the tip of the cantilever, and/or the direction along which the tip of the cantilever pitches. The x-dimension and y-dimension may be perpendicular to the z-dimension (e.g., as defined at the tip of the cantilever). The x-dimension may be the width-wise dimension of a cantilever that has an elongated cross-sectional shape, and may be illustrated herein (e.g., in cantilever diagrams) as the horizontal dimension. The y-dimension may be the thickness dimension of a cantilever that has an elongated cross-sectional shape, and may be illustrated herein (e.g., in cantilever diagrams) as the vertical dimension. In the example of FIG. 1, the z-dimension is in and out of the page, the y-dimension is vertical, and the x-dimension is horizontal. While this disclosure describes the positive z-direction as the direction in which the tip of the cantilever pitches, a person of skill in the art will appreciate that sign convention for the direction of cantilever pitch is arbitrary. For instance, the sign of the z-direction and the related orientation (e.g., “handedness”) of the Cartesian convention does not affect the description herein.

Any of the systems, methods, techniques, and/or features disclosed herein may be combined, in whole or in part, with any other disclosed systems, methods, techniques, and/or features. As used herein, the singular forms “a”, “an”, and “the” include the plural reference unless the context clearly dictates otherwise. Reference to “about” a value or parameter or “approximately” a value or parameter herein includes (and describes) variations that are directed to that value or parameter per se. For example, description referring to “about X” includes description of “X”. It is understood that aspects and variations of the invention described herein include “consisting of” and/or “consisting essentially of” aspects and variations. When a range of values or values is provided, it is to be understood that each intervening value between the upper and lower limit of that range, and any other stated or intervening value in that stated range, is encompassed within the scope of the present disclosure. Where the stated range includes upper or lower limits, ranges excluding either of those included limits are also included in the present disclosure.

Photonic System with an Active Curving Cantilever

FIG. 1 illustrates a photonic system 100 with an active curving cantilever 102 (e.g., piezoelectrically actuated cantilever) that can enable two-dimensional beam scanning, such as a two-dimensional Lissajous pattern. The cantilever 102 may include several layers: a sacrificial (i.e., release) layer 104, a first, bottom dielectric layer 106, and a second, top dielectric layer 108. Sacrificial layer 104 may bind cantilever 102 to a substrate (e.g., a substrate of an integrated circuit chip) and may be any material layer deposited in the layer stack of cantilever 102 that can be preferentially removed or etched away, e.g., by a wet chemical etch or a gaseous chemical etch, compared to the other materials that constitute cantilever 102 in order to release the overlying layers of cantilever 102 (layers 106-108) from the substrate. For example, sacrificial layer 104 may be a layer of amorphous silicon that can be etched away using a xenon difluoride gas that does not etch the overlying cantilever layers (layers 106-108). An amorphous silicon sacrificial layer can also be removed using various concentrations of potassium hydroxide. If the overlying dielectric layers 106 and 108 do not comprise silicon dioxide, then sacrificial layer 104 can be silicon dioxide or another oxide glass and may be removed using a wet etch of hydrofluoric acid.

Dielectric layers 106 and 108 may be any thin film dielectrics having intrinsic stresses (e.g., silicon dioxide or silicon nitride). The intrinsic stress of layer 108 may be different (e.g., more compressive or more tensile) than the intrinsic stress of layer 106; this difference may be the result of material or chemical differences between layer 106 and layer 108 or, if layer 106 and layer 108 have the same chemical composition, the result of differences in the conditions under which each layer was deposited during the fabrication of cantilever 102. For example, if both layer 106 and layer 108 comprise silicon dioxide or silicon nitride, layer 106 may be configured to have a different intrinsic stress than layer 108 by depositing layer 106 at a different flow rate than the flow rate used to deposit layer 108. Other deposition conditions that may be varied in order to configure the stresses of layers 106 and 108 include the mixture of precursor gases used during deposition, plasma pressure, plasma frequency, and power in a chemical vapor deposition chamber. Post-deposition annealing can also change the intrinsic stress of an as-deposited film.

When sacrificial layer 104 is removed and cantilever 102 is released from the substrate, the gradient of intrinsic stress between layer 106 and layer 108 may cause cantilever 102 to deflect along its length relative to the substrate, such that the cantilever deflects along its lengthwise z axis and the tip of the cantilever thus moves in the x dimension and/or y dimension. Reference herein to the length of a cantilever (e.g., description of a cantilever deflecting or deforming “along its length”) may be interpreted as reference to the longest, longitudinal dimension of the cantilever, and may be referred to as a z-dimension of the cantilever. Reference to the width of a cantilever (e.g., description of a cantilever deflecting or deforming “along its width”) may be interpreted as reference to the shorter, x-dimensional dimension of cantilever that is co-planar with the longitudinal dimension of cantilever 100, and may be referred to as an x-dimension of the cantilever. The thickness of the cantilever may be the third Cartesian dimension, referred to as a y-dimension of the cantilever and perpendicular to both the x-dimension and z-dimension.

While this disclosure describes the positive z-direction as the direction in which light travels in the waveguide along the length of the cantilever, a person of skill in the art will appreciate that sign convention for the direction of light propagation is arbitrary. For instance, the sign of the z-direction and the related orientation (e.g., “handedness”) of the Cartesian convention does not affect x-directional and y-directional displacement equations, voltage equations, etc. described herein.

In order to concentrate the deflection caused by the gradient of intrinsic stress between layer 106 and layer 108 in the longitudinal dimension and to reduce lateral strain in cantilever 102 that can cause cantilever 102 to curl along its width, layer 108 can be geometrically patterned atop layer 106 such that lateral strain is redirected along the length of cantilever 102 to increase the amount by which cantilever 102 deflects along its length. In some embodiments, the geometric patterning of the dielectric layer 108 causes cantilever 102 to deflect along its length in a direction away from the substrate. In other embodiments, the geometric patterning of the dielectric layer 108 causes cantilever 102 to deflect along its length in a direction toward the substrate (e.g., causes cantilever 102 to form a semi-circular or semi-ellipsoid arch relative to the substrate). In other embodiments, the geometric patterning of the dielectric layer 108 causes cantilever 102 to twist one or more times along its length to form a (partial) helix. In other embodiments, the geometric patterning of the dielectric layer 108 causes cantilever 102 to twist along its length and to deflect along its length.

The cantilever 102 may include a plurality of waveguides (e.g., number of waveguides, N_{WG}) patterned in the dielectric layer 108. For instance, the cantilever 102 may include a waveguide 110 oriented along the length of cantilever 102 and that forms a channel within the dielectric layer 108. Waveguide 110 may be formed using a dielectric material with low optical loss (e.g., optical loss of less than 1 dB/cm). Waveguide 110 may be oriented parallel to the length of the cantilever and can be positioned proximally or distally to the center of cantilever 102. Light from a light source 120, such as a laser, may be coupled into the plurality of waveguides (e.g., the waveguide 110) of the cantilever 102. In some embodiments, each waveguide of the plurality of waveguides is coupled to a light source, such as the light source 120. For instance, a first waveguide of the cantilever 102 may receive light from a light source that outputs light at a frequency A, and a second waveguide of the cantilever 102 may receive light from a light source that outputs light at a frequency B.

The cantilever 102 can be configured such that the deflection is actively controllable. That is, rather than being configured to deflect and remain deflected following its release from its substrate, the cantilever 102 may be configured to deflect on-demand. Control of the deflection of the cantilever 102 may be binary (e.g., cantilever 102 may be switchable between an undeflected state and a single deflected state), discrete (e.g., cantilever 102 may be switchable between an undeflected state and two or more distinct deflected states), or continuous (e.g., cantilever 102 may be adjustable between a continuum of configurations between an undeflected state and a fully deflected state).

Cantilever 102 may comprise a piezoelectric layer 112 of piezoelectric material overlying a first dielectric layer 106. Sandwiching piezoelectric layer 112 may be a pair of conductive electrodes 114 and 122. Electrodes 114 and 122 may be electrically connected (e.g., by wires or conductive traces in the substrate to which cantilever 102 is anchored) to one or more voltage sources (e.g., a battery, an AC/DC power supply, etc.), such as voltage source 118. Applying a voltage across piezoelectric layer 112 using the voltage source 108 may cause piezoelectric layer 112 to mechanically deform. If the voltage is applied to piezoelectric layer 112 when sacrificial layer 104 is removed and cantilever 102 is released, the mechanical deformation of piezoelectric layer 112 may cause cantilever 102 to deflect along its length.

In some embodiments, the one or more voltage sources, such as the voltage source 118, may be configured to apply AC voltages across the piezoelectric layer 112, and the AC voltages may be controlled by a controller 122. As such, the piezoelectric layer 112 may be controlled by a controller 122 that is configured to generate AC signals. In some embodiments, controller 112 comprises a function generator or an arbitrary waveform generator. In other embodiments, controller 112 enables digital signal driving. For example, controller 112 can generate the AC signals using a clock running on an embedded processor, a field programmable gate array (FPGA), a phase lock loop (PLL), or a voltage-controlled oscillator (VCO). A digital controller may simplify the electronic control of cantilever 102 and increase the scalability of the photonic system 100.

When cantilever 102 is driven with AC voltages of specific frequencies, cantilever 102 may demonstrate one or more y-directional resonances (at frequencies f_{Y}) and one or more x-directional resonances (at frequencies f_{X}). This may enable the tip of the waveguide 110 of cantilever 102 (e.g., tip of the cantilever 102) to be moved both y-directionally and x-directionally. The frequencies at which cantilever 102 demonstrates the y-directional and x-directional resonances can be observed from kilohertz to megahertz rates and can vary based on the length, width, and geometrical properties of cantilever 102. The light from the light source 120 that is output from the tip of cantilever 102 through the waveguide 110 (e.g., the light propagates in a positive z-direction) can be projected in two-dimensional space by driving cantilever 102 at these resonances while modulating the light (e.g., such as turning on and off the light from the light source 102 at specific intervals in time). Cantilever 102 can therefore be used for 2D beam steering applications including (but not limited to) projecting a beam spot onto an atomic array of color centers (e.g., in a quantum computing system), performing 2D LiDAR scanning, and projecting an image in 2D space, such as projecting a Lissajous pattern in 2D space.

In some embodiments, two dimensional control of cantilever 102 is accomplished by driving piezoelectric layer 112 with an AC voltage v(t)=A_{X} sin(f_{X}t+φ_{X})+A_{Y} sin(f_{Y}t+φ_{Y}), where X refers to the x-dimension (i.e., the width) of cantilever 102 and Y refers to the y-dimension of cantilever 102. While driving piezoelectric layer 212, light that is input into waveguide 110 may be modulated using an optical modulator (e.g., a shutter or an acousto-optic modulator). This control process can be used to perform a raster scan or to trace a Lissajous pattern. The phases φ_{X}, φ_{Y} can be adjusted to change the shape of the Lissajous pattern. Synchronously modulating the input light with the pattern traced by the cantilever tip may display an image or allow a specific pattern to be traced.

Raster scanning can be accomplished via low-frequency, off-resonant signal scanning of the one dimension (e.g., the x-directional cantilever axis) and high-frequency, resonant signal scanning of a perpendicular dimension (e.g., the y-directional cantilever axis). The light modulating signal may project scanlines. Lissajous scanning (e.g., projecting the Lissajous pattern in 2D space) can be performed using dual resonances to simultaneously scan both the y-directional and x-directional cantilever axes.

The repetition rate may be the greatest common divisor (GCD) between the y-directional resonance frequency and the x-directional resonance frequency. The refresh rate may be the speed (in Hz) at which cantilever 102 traces a pattern (e.g., projects an image) across a given imaging plane and returns to a starting x-directional and y-directional position. The refresh rate may depend on the ratio between the y-directional resonance frequency and the x-directional resonance frequency. A fill factor may be the percentage of an area of the imaging plane that is traversed by at least one beam spot projected from the cantilever. For applications such as atomic color center excitation, a high repetition rate can be beneficial. For applications such as image projection and LiDAR scanning, a high fill rate may be more desirable.

### Crossbar Patterning

In some embodiments, the second dielectric layer 108 of the cantilever 102 may comprise a plurality of crossbars oriented at an angle relative to the z-dimension of the cantilever 102 to control curvature in an x-dimension (e.g., suppressing width-wise curving) of the cantilever 102. For instance, the plurality of crossbars may be deposited on a surface of the second dielectric layer 108 of the cantilever 102. Each crossbar may have a length l_{c}, a width w_{c}, and a height h_{c} and may be oriented at an angle θ_{c} relative to the length of cantilever 102.

Relative to its width w_{c}, the length l_{c} of a given crossbar may be small. For example, the length l_{c} of a given crossbar may be 90%, 80%, 70%, 60%, 50%, 40%, 30%, 20%, or 10% smaller the width w_{c} of the crossbar. In some embodiments, the length l_{c} of a given crossbar is approximately (e.g., is within 1%, 10%, 15%, or 20% of) 0.5, 0.75, 1, 1.25, 1.5, 1.75, 2, 2.25, 2.5, 2.75, or 3 microns In some embodiments, the length l_{c} of a given crossbar is greater than or equal to 0.1, 0.15, 0.2, 0.25, 0.3, 0.35, 0.4, 0.45, or 0.5 μm. In some embodiments, the length l_{c} of a given crossbar is less than or equal to 5, 4.5, 4, 3.5, 3, 2.5, 2, 1.5, or 1 μm. Each crossbar may have the same length l_{c}, or the lengths of crossbars 210 may vary, e.g., may vary along the length of cantilever 102 or along the width of cantilever 102. In some embodiments, the length l_{c} of a crossbar may taper along the width or the height of the crossbar.

A crossbar may be as wide as the underlying layers (e.g., first dielectric layer 106) of cantilever 102 or may be more or less wide than the underlying layers of (e.g., first dielectric layer 106) of cantilever 102. In some embodiments, the width w_{c} of a given crossbar is greater than or equal to 1, 5, 10, 15, 25, 50, 75, 100, 200, 300, 400, or 500 μm. In some embodiments, the width w_{c} of a given crossbar is less than or equal to 1000, 900, 800, 700, 600, 500, or 400 μm. The width w_{c} of each crossbar may affect the amount by which the second dielectric layer 108 can suppress and redirect the lateral strain in cantilever 102 along the length of the cantilever 102). In some embodiments, each crossbar has the same width w_{c}; in other embodiments, the widths of crossbars vary, e.g., along the length of cantilever 102 or along the width of cantilever 102. In some embodiments, the width w_{c} of a crossbar may taper along the length or the height of the crossbar.

Crossbars may or may not protrude from the surface of the second dielectric layer 108. If a given crossbar does not protrude from the surface of the second dielectric layer 108, its height h_{c} relative to the surface of the second dielectric layer 108 may be negligible. If a given crossbar does protrude from the surface of the second dielectric layer 108, its height h_{c} relative to the surface of the second dielectric layer 108 may be greater than 0 μm and less than or equal to 0.05, 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, 1, 1.05, 1.1, 1.15, 1.2, 1.25, 1.3, 1.35, 1.4, 1.45, 1.5, 1.55, 1.6, 1.65, 1.7, 1.75, 1.8, 1.85, 1.9, 1.95 or 2 μm. Each crossbar can have the same height h_{c}, or the heights of crossbars may vary, e.g., along the length of cantilever 102 or along the width of cantilever 102. In some embodiments, the height h_{c} of a crossbar may taper along the length or the width of the crossbar.

The angle θ_{c} at which a given crossbar is oriented relative to the length of cantilever 102 may be an angle between a line parallel to the length of cantilever 102 and a line parallel to the width of the crossbar. In some embodiments, a crossbar is patterned such that its width is orthogonal to the length of cantilever 102—i.e., the angle θ_{c} at which the crossbar is oriented relative to the length of cantilever 102 may be approximately 90°. A crossbar can also be patterned such that its width is oriented diagonally with respect to the length of cantilever 102—e.g., the angle θ_{c} at which the crossbar is oriented relative to the length of cantilever 102 may be less than 90° or greater than 90°. In some cases, each crossbar may be oriented at the same angle θ_{c} relative to the length of cantilever 102. In others, the orientations of crossbars may vary, e.g., along the length of cantilever 102 or along the width of cantilever 102. The angle(s) at which crossbars are oriented relative to the length of cantilever 102 may affect the direction in which cantilever 102 deflects when released from the substrate.

The patterning of the plurality of crossbars may be periodic along the length of cantilever 102. That is, the patterning of crossbars may repeat after a given distance T along the length of cantilever 102, where T is the period of the crossbar patterning. If each crossbar has the same geometry and the same orientation relative to the length of cantilever 102, the period T of the crossbar patterning may be the z-dimensional separation distance between analogous points on adjacent crossbars. In such cases, the period T may be directly related to the z-dimensional density of crossbars. On the other hand, if the geometries or the orientations of crossbars varies along the length of cantilever 102, the period T of the crossbar patterning may be the z-dimensional separation distance between analogous points in repeating crossbar pattern segments. For example, if the second dielectric layer 108 is divided into repeating segments having the following crossbar pattern:
a first crossbar oriented at a first angle θ_{c1};
a second crossbar oriented at a second angle θ_{c2};
a third crossbar oriented at a third angle θ_{c3},
   then the period T of the crossbar patterning may be the z-dimensional separation distance between analogous points on the first crossbar in a first segment and the first crossbar in a second segment that is adjacent to the first segment.

In some embodiments, the period T of the crossbar patterning is greater than or equal to 0.05, 0.1, 0.5, 1, 1.5, 2, 2.5, 3, 3.5, 4, 4.5, 5, 5.5, 6, 6.5, 7, or 7.5 μm. In some embodiments, the period T of the crossbar patterning is less than or equal to 15, 14.5, 14, 13.5, 13, 12.5, 12, 11.5, 11, 10.5, 10, 9.5, 9, 8.5, 8, or 7.5 μm. In some embodiments, the period T is greater than or equal to 20, at least 30, at least 40, at least 50, at least 60, at least 70, at least 80, at least 90, or at least 100 μm. The period T of the crossbar patterning can remain constant along the length of cantilever 102 or can vary (e.g., increase or decrease) along the length of cantilever 102.

If each crossbar has the same length l_{c}, the duty cycle of the crossbar patterning, defined as the ratio of the crossbar length l_{c} to the period T of the crossbar patterning (Duty Cycle=_{c}/T) may range between 0 and 1. For example, the crossbar patterning can have a duty cycle in the range 0-0.25, 0-0.5, 0-0.75, or 0-0.99. If second dielectric layer 108 has a crossbar patterning with a low duty cycle (e.g., a duty cycle less than 0.25), second dielectric layer 108 may be capable of redirecting a greater amount of lateral strain in cantilever 102 along the length of cantilever 102; as such, a cantilever having low duty cycle crossbar patterning may, when released from its substrate, deflect along its length by a greater amount than a cantilever having a higher duty cycle crossbar patterning.

### Crossbar Patterning to Modify Cantilever ‘Pitch’

FIGS. 2A-2C illustrate aspects of the crossbar patterning on a cantilever, such as cantilever 102 of FIG. 1. FIG. 2A shows a schematic of the stress engineering of the crossbars on a cantilever. As described herein, crossbars apply top lateral expansion (see label ‘Top Lateral Expansion), and combined with the bottom lateral compression (see label ‘Bottom Lateral Compression’) of the underlying bulk oxide, the crossbars may lead to bottom longitudinal expansion (see label ‘Bottom Longitudinal Expansion’) of increased pitch curling (e.g., positive longitudinal “pitch,” see label ‘Positive Longitudinal ‘Pitch’’) of the overall cantilever. As used herein, “pitch” may refer to the orientation of the tip of the cantilever in three-dimensional space, similar to the manner in which the term pitch is used in the context of “pitch,” “roll,” and “yaw” in reference to aircraft orientation. FIG. 2B shows example cantilevers curled upward with variable pitch crossbars due to varying periods T of crossbar patterning on the cantilever, such as described herein, from 4 to 8 μm (see FIG. 2B (i)). FIG. 2B (ii) shows that crossbars cause overall x-directional widthwise downward curvature at the cantilever tip, which enhances longitudinal pitch curling. FIG. 2C shows a plot of radius of curvature (mm) as a function of oxide crossbar density (per mm) and differential strain (ϵ₂−ϵ₁) as a function of oxide crossbar density, in which ϵ₂ is the strain of a portion of a layer stack of a cantilever that includes the piezoelectric layer 112 (e.g., such as the portion of layers including and below second electrode of cantilever 102 of FIG. 1) and ϵ₁ is the strain of a different portion of a layer stack of a cantilever that includes optical dielectric layers (e.g., such as the portion of layers including waveguide 110 and second dielectric layer 108 of cantilever 102 of FIG. 1). In some embodiments, a large density of crossbars (e.g., such as greater than 100 crossbars/mm) may be required to overcome the bulk thin films (e.g., first and second dielectric layers of a cantilever) transverse inward stresses that decrease overall longitudinal curling of the cantilever. For instance, such as demonstrated in FIG. 2C, increased crossbar density increases differential strain between the films, and thus, increases longitudinal curling (e.g., reduces radius of curvature).

In some embodiments, a cantilever (e.g., cantilever 102) may comprise the following layer stack: 1) silicon dioxide (SiO₂) (e.g., first dielectric layer 106 of cantilever 102), 2) aluminum (Al) (e.g., first electrode 114 of cantilever 102), 3) piezo-actuatable aluminum nitride (AlN) (e.g., piezoelectric layer 112 of cantilever 102), 4) Al (e.g., second electrode 116 of cantilever 102), 5) SiO₂ (e.g., second dielectric layer 108 of cantilever 102), 6) SiN (e.g., waveguide 110 of cantilever 102), and 7) SiO₂ (e.g., continuation of second dielectric layer 108 of cantilever 102 after SiN layer) ((See M. Dong, G. Clark, A. J. Leenheer, M. Zimmermann, D. Dominguez, A. J. Menssen, D. Heim, G. Gilbert, D. Englund, and M. Eichenfield, “High-speed programmable photonic circuits in a cryogenically compatible, visible-near-infrared 200 mm CMOS architecture,” Nat. Photonics 16, 59-65 (2021))).

As described herein, upon release, the films (e.g., the first dielectric layer 106 and/or second dielectric layer 108 of cantilever 100) expand or contract in an isotropic manner according to their intrinsic stress values (e.g., ϵ₂, ϵ₁) resulting in a static curvature of the cantilever (see FIG. 2B). Achieving upward curvature therefore may require engineering a larger compressive stress on the bottom oxide (e.g., first dielectric layer 106 of cantilever 102) and piezo layers (2-4) compared to the top optical layers (5-7). A continuous layer stack (e.g., a layer stack of a cantilever without crossbar patterning on a second dielectric layer of the cantilever), even without the highly compressive SiN layers (e.g., waveguide 110 of cantilever 102 or a plurality of waveguides of cantilever 102), may have large downward curvature due to the compressive top-SiO₂ layers (e.g., second dielectric layer 108 of cantilever 102). However, large upward curvature may be achieved by modifying the directionality of the stress of the top-SiO₂ layers by patterning them with crossbar-structures perpendicular to the length of the cantilever, such as described in reference to FIG. 1.

Patterning the top-SiO₂ layers (e.g., second dielectric layer 108 of cantilever 102) with crossbars has two effects: 1) The crossbar patterning prevents the buildup of longitudinal compressive stress via the top layers (e.g., layers 5-7) while 2) the lateral stress of the top layers (e.g., layers 5-7) causes lateral compression, and longitudinal expansion, of the bottom layers (see FIG. 2A). This lateral compression is evident in the SEM (scanning electron microscope) image of the cantilever tip (see FIG. 2B). Absent crossbars, the cantilever has moderate isotropic curvature. For instance, the cantilever, absent crossbars, may have a radius of curvature in a range of 2 mm-3 mm. Increasing the density of crossbars increases the longitudinal curvature (see FIG. 2C, which is equivalent to a differential strain between the top (e.g., second dielectric layer 108 of cantilever 102) and bottom layers (e.g., first dielectric layer 106 of cantilever 102). For instance, increasing the density of crossbars may decrease the cantilever's radius of curvature to a range of 600 μm-800 μm. The differential strain is given by:

$$Δ ϵ = {ϵ}_{2} - {ϵ}_{1} = h / R ,$$

where h is the distance between the center of the two films (e.g., first dielectric layer 106 and second dielectric layer 108 of cantilever 102) and R is the radius of curvature of the cantilever (see FIG. 2C). In some embodiments, the optimal density of crossbars (e.g., the crossbar density required to overcome the bulk thin films transverse inward stresses) will differ based on the number of SiN waveguides. However, the optimal density of crossbars will follow a similar trend as FIG. 2C as the number of SiN waveguides varies. In some embodiments, a crossbar pitch of 8 μm (e.g., crossbar patterning period T) with each crossbar 1 μm long (e.g., l_{c}) provides optimal upward “pitch” for cantilevers with 1 or 2 waveguides (e.g., waveguide 110 of cantilever 102). An optimal upward “pitch” may refer to the largest upward pitch of the cantilever (e.g., smallest radius of curvature of the cantilever). For instance, a radius of curvature less than or equal to 1 mm may be considered an optimal upward “pitch” of a cantilever. In some embodiments, a plot of the radius of curvature of a 50 μm wide cantilever with a single waveguide as a function of crossbar density, such as FIG. 2C, is fit to a function of the form y=a/x−b—where y is radius of curvature data and x is crossbar density data.

### Crossbar Patterning to Modify Cantilever ‘Roll’

In some embodiments, roll, as well as the pitch, of a cantilever, such as cantilever 102 of FIG. 1. is modified via the crossbar patterning. “Roll” may be used herein in the same “roll,” “pitch,” and “yaw” convention referenced above. FIG. 3 shows aspects of modifying a cantilever's pitch and roll via crossbar engineering. FIG. 3A shows that the local curl of the cantilevers is orthogonal to the direction of the crossbars. For a fixed crossbar angle (e.g., θ_{c}) counterclockwise from horizontal dimension (x-dimension) of the cantilever (e.g., counterclockwise relative to the width of the cantilever), the cantilevers will pitch and roll to the right, such as depicted by cantilever 202 and cantilever 204. Cantilever 202 and 204 may be any cantilever described herein, such as cantilever 102 of FIG. 1. FIG. 3B shows that varying the crossbar angle along the length of the cantilever (e.g., varying θ_{c} along the length of the cantilever) will induce local variation in the roll of the cantilever. For instance, alternating the crossbars counterclockwise and clockwise causes the cantilever to roll back and forth (e.g., right to left) while still pitching upward (see FIG. 3B). FIG. 3C shows a single mode optical fiber packaged to a cantilever of a photonic chip using UV cured adhesive.

As described herein, crossbars generate curvature orthogonal to their orientation. As such, the cantilever may be “rolled” by varying the angle of the crossbars (e.g., θ_{c}) with respect to the directionality of the cantilever. To explore this effect, several cantilevers were fabricated with different angled crossbars. For a fixed crossbar angle (e.g., θ_{c}) along the length of the device, the cantilevers roll to the side as well as pitch upward (see cantilever 202 and cantilever 204 of FIG. 3A). While pitch and roll are coupled in the cantilever, varying the angle of the crossbars along the length of the cantilever allows more precise control of relative pitch and roll to create a desired θ (where θ is the pitch of the cantilever) and φ (where φ is the roll of the cantilever) of waveguide output. Adjusting the crossbar angles (e.g., θ_{c}) back and forth counterclockwise and clockwise relative to the horizontal dimension of the cantilever (x-dimension), causes the cantilever to roll back and forth while pitching upward (see FIG. 3B). In some embodiments, a yaw-type rotation can be simulated by both rolling the cantilever and pitching the cantilever to achieve a yaw direction. The combined use of static pitch and roll control, described herein, and 2-D piezo control of the cantilever, described herein, enables full channel-by-channel coarse and fine alignment of the cantilever to fiber arrays or directly to other photonic chips with arbitrary 3D orientations, thus enabling a direct, non-planar interface between multiple photonic chips via the cantilever. These small footprint tailorable devices can be further tiled for large, high-density arrays and fabricated in the same platform used to fabricate other scalable cryo-compatible high-speed photonics (See M. Dong, G. Clark, A. J. Leenheer, M. Zimmermann, D. Dominguez, A. J. Menssen, D. Heim, G. Gilbert, D. Englund, and M. Eichenfield, “High-speed programmable photonic circuits in a cryogenically compatible, visible-near-infrared 200 mm CMOS architecture,” Nat. Photonics 16, 59-65 (2021)). As such, the cantilevers described herein can be used in photonically or electronically active devices. However, the cantilevers described herein can be used solely as mechanical actuators (e.g., not used to enable a direct, non-planar interface between multiple photonic chips), such as illustrated in FIGS. 6A-9.

### Modifying Width of a Cantilever

In some embodiments, the width of the cantilever (e.g., such as cantilever 102 of FIG. 1) patterned with crossbars is associated with the radius of curvature of the cantilever. FIG. 4 shows a plurality of cantilevers with various widths and illustrates that cantilever width may be associated with the radius of curvature of the cantilever. For instance, the wider the cantilever, the smaller the radius of curvature. In some embodiments, a cantilever is tapered such that the cantilever tip is the narrowest portion of the cantilever. In some embodiments, the curvature of a tapered cantilever progressively flattens (and may reverse, such that the cantilever curves downwards) as a function of the length of the cantilever. In some embodiments, the curvature of a tapered cantilever is associated with the taper profile of the tapered cantilever. For instance, a tapered cantilever with a quadratic taper profile exhibits a different curvature than a tapered cantilever with a linear taper profile. As such, the curvature profile of a cantilever patterned with crossbars may be engineered (e.g., designed, programmed, etc.) by adjusting the width of the cantilever.

### Compound Structures

In some embodiments, a plurality of cantilevers (e.g., such as cantilever 102 of FIG. 1) patterned with crossbars are combined to form a compound structure. Each cantilever of the compound structure has crossbars patterned with a specific period, T, and angle, θ_{c}, relative to the length of the cantilever, such as described herein. As such, each cantilever of the compound structure may affect a local pitch and roll of the compound structure, such that a first portion of the compound structure exhibits a pitch and roll different than a second portion of the compound structure. For instance, FIG. 5A illustrates a compound structure 500a formed from a plurality of cantilevers patterned with crossbars. The compound structure 500a includes a portion 502 that exhibits a different pitch and roll than a portion 504. The compound structure 500a may exhibit an overall pitch and roll in accordance with the pitch and roll of each cantilever of the compound structure 500a. FIG. 5B illustrates a first compound structure 500b, a second compound structure 500c, and a third compound structure 500d. Each compound structure of FIG. 5B exhibits a different overall pitch and roll in accordance with the pitch and roll of each cantilever of each compound structure.

### Micron-Scale Gripping Actuators

Micron-scale gripping actuators can be formed by counter-posing two or more cantilevers (e.g., such as cantilevers described herein), as shown in FIGS. 6A-6C. The topmost dielectric layers on the cantilevers in a gripping actuator may be patterned with crossbars such that, when the cantilevers are released, the cantilevers curl toward one another. The deflection of the cantilevers in a gripping actuator may be piezoelectrically controlled so that the gripping actuator can be selectively opened and closed. These actuators may be implemented in micro-robotic systems.

Folding Cantilevers into 3D Shapes

In some embodiments, the crossbar patterning of a cantilever, such as cantilever 102 of FIG. 1, may be used to ‘fold’ the cantilever into a 3D shape. For instance, a cantilever can be deterministically configured to assume a helical structure when released by patterning its topmost dielectric layer with crossbars that are oriented diagonally with respect to the cantilever length, as illustrated in FIG. 7. More intricate three-dimensional shapes such as those depicted in FIGS. 8 and 9 may be obtained by patterning the crossbars such that the radius of curvature R of the helix varies along the length of the cantilever when the cantilever is released. For example, a ball may be created by patterning the crossbars such that, when the cantilever is released, the radius of curvature R of the cantilever starts out relatively small near one end, increases along the cantilever length, and then decreases again toward the other end (FIG. 8). A toroid may be created by modulating the radius of curvature R at the same spatial period as the helical twist such that a larger radius R appears at the same point in the twist, causing the helix to turn and, eventually, close on itself (FIG. 9). Additional shapes can be obtained via similar modulation of the stress magnitude and directionality. In some embodiments, the stress magnitude and directionality is further modulated by patterning the electrodes (e.g., first electrode 114 and/or second electrode 116) and/or the piezoelectric layer (e.g., piezoelectric layer 112) such that the stress magnitude and directionality varies as a function of the electrode and/or piezoelectric layer patterning. Complex structures may be self-assembled by combining multiple cantilevers configured to obtain more basic shapes. FIG. 10 is an image of a cantilever in a helix shape. The cantilever of FIG. 10 is an exemplary embodiment of a cantilever configuration enabled via the pitch and roll control described herein.

FIG. 11 illustrates an example of a computing system 1100 that may be used for any one of the computing systems and devices described herein, such as for controller 122 of FIG. 1. System 1100 can be a computer connected to a network. System 1100 can be a client computer, a server, a router, a hub, an access point, or any other computing device that can send and/or receive wireless signals or non-wireless signals. As shown in FIG. 11, system 1100 can be any suitable type of microprocessor-based system, such as a personal computer, workstation, server, or handheld computing device (portable electronic device) such as a phone or tablet. The system can include, for example, one or more of a processor 1110, input device 1120, output device 1130, storage 1140, and communication device 1160. Input device 1120 and output device 1130 can generally correspond to those described above and can either be connectable or integrated with the computer.

Input device 1120 can be any suitable device that provides input, such as a touch screen, keyboard or keypad, mouse, gesture recognition component of a virtual/augmented reality system, or voice recognition device. Output device 1130 can be or include any suitable device that provides output, such as a touch screen, haptics device, virtual/augmented reality display, or speaker.

Storage 1140 can be any suitable device that provides storage, such as an electrical, magnetic, or optical memory, including a RAM, cache, hard drive, removable storage disk, or other non-transitory computer-readable medium. Communication device 1160 can include any suitable device capable of transmitting and receiving signals over a network, such as a network interface chip or device. The components of the computer can be connected in any suitable manner, such as via a physical bus or wirelessly.

Software 1150, which can be stored in storage 1140 and executed by processor 1110, can include, for example, the programming that embodies the functionality of the present disclosure (e.g., as embodied in the devices as described above). For example, software 1150 can include one or more programs for generating AC voltages applied across a piezoelectric layer of a cantilever, such as described in reference to FIG. 1.

Software 1150 can also be stored and/or transported within any non-transitory computer-readable storage medium for use by or in connection with an instruction execution system, apparatus, or device, such as those described above, that can fetch instructions associated with the software from the instruction execution system, apparatus, or device and execute the instructions. In the context of this disclosure, a computer-readable storage medium can be any medium, such as storage 1140, that can contain or store programming for use by or in connection with an instruction execution system, apparatus, or device.

Software 1150 can also be propagated within any transport medium for use by or in connection with an instruction execution system, apparatus, or device, such as those described above, that can fetch instructions associated with the software from the instruction execution system, apparatus, or device and execute the instructions. In the context of this disclosure, a transport medium can be any medium that can communicate, propagate, or transport programming for use by or in connection with an instruction execution system, apparatus, or device. The transport-readable medium can include, but is not limited to, an electronic, magnetic, optical, electromagnetic, or infrared wired or wireless propagation medium.

System 1100 may be connected to a network, which can be any suitable type of interconnected communication system. The network can implement any suitable communications protocol and can be secured by any suitable security protocol. The network can comprise network links of any suitable arrangement that can implement the transmission and reception of network signals, such as wireless network connections, T1 or T3 lines, cable networks, DSL, or telephone lines.

System 1100 can implement any operating system suitable for operating on the network. Software 1150 can be written in any suitable programming language, such as C, C++, Java, or Python. In various aspects, application software embodying the functionality of the present disclosure can be deployed in different configurations, such as in a client/server arrangement or through a Web browser as a Web-based application or Web service, for example.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the techniques and their practical applications. Others skilled in the art are thereby enabled to best utilize the techniques and various embodiments with various modifications as are suited to the particular use contemplated.

Although the disclosure and examples have been fully described with reference to the accompanying figures, it is to be noted that various changes and modifications will become apparent to those skilled in the art. Such changes and modifications are to be understood as being included within the scope of the disclosure and examples as defined by the claims. Finally, the entire disclosure of the patents and publications referred to in this application are hereby incorporated herein by reference.

1. A cantilever comprising:
a first dielectric layer, wherein the first dielectric layer has a first intrinsic stress;
a second dielectric layer overlying the first dielectric layer, wherein the second dielectric layer has a second intrinsic stress that is different than the first intrinsic stress,
wherein the cantilever is curved along a lengthwise z-dimension of the cantilever due to a difference between the first and second intrinsic stresses, and
wherein the second dielectric layer comprises a plurality of crossbars angled relative to an x-dimension width of the cantilever to control curvature in the x-dimension width of the cantilever, to induce a change in pitch along the length of the cantilever, and to induce a change in roll along the length of the cantilever.

2. The cantilever of claim 1, wherein:
all crossbars of the plurality of crossbars are oriented at a first non-orthogonal angle relative to the width of the cantilever, such that the change in roll along the length of the cantilever is monotonic.

3. The cantilever of claim 2, wherein:
all crossbars of the plurality of crossbars have a regular periodic spacing with respect to one another, such that the roll along the length of the cantilever has a constant rate of change with respect to lengthwise position along the cantilever.

4. The cantilever of claim 1, wherein:
a first crossbar of the plurality of crossbars is oriented at a first non-orthogonal angle relative to the width of the cantilever, and
a second crossbar of the plurality of crossbars is oriented at a second non-orthogonal angle relative to the width of the cantilever,
the first non-orthogonal angle is different from the second non-orthogonal angle.

5. The cantilever of claim 4, wherein:
the first non-orthogonal angle and the second non-orthogonal angle are both angled in a common direction with respect to the width of the cantilever, such that the change in roll along the length of the cantilever is monotonic, and such that the roll along the length of the cantilever has a varying rate of change with respect to lengthwise position along the cantilever.

6. The cantilever of claim 4, wherein:
the first non-orthogonal angle and the second non-orthogonal are angled in different directions with respect to the width of the cantilever,
such that the change in roll along the length of the cantilever is non-monotonic.

7. The cantilever of claim 1, comprising a piezoelectric layer disposed between the first layer and the second layer.

8. The cantilever of claim 1, comprising one or more waveguides.

9. A photonic system comprising:
a photonic integrated circuit (PIC) chip comprising the cantilever of claim 1.

10. A cantilever comprising:
a first dielectric layer, wherein the first dielectric layer has a first intrinsic stress;
a second dielectric layer overlying the first dielectric layer, wherein the second dielectric layer has a second intrinsic stress that is different than the first intrinsic stress,
wherein the cantilever is curved along a lengthwise z-dimension of the cantilever due to a difference between the first and second intrinsic stresses, and
wherein the second dielectric layer varies in thickness along a length of the cantilever and along an x-dimension width of the cantilever, such that the varying thickness controls curvature in one or more dimensions of the cantilever.

11. The cantilever of claim 10, wherein the second dielectric layer comprises a pattern of troughs formed in the second dielectric layer that varies along the length and in the x-dimension width.

12. The cantilever of claim 10, wherein a change in roll along the length of the cantilever is monotonic.

13. The cantilever of claim 12, wherein the roll along the length of the cantilever has a constant rate of change with respect to lengthwise position along the cantilever.

14. The cantilever of claim 10, wherein the roll along the length of the cantilever has a varying rate of change with respect to lengthwise position along the cantilever.

15. The cantilever of claim 10, wherein the change in roll along the length of the cantilever is non-monotonic.

16. The cantilever of claim 10, comprising a piezoelectric layer disposed between the first layer and the second layer.

17. The cantilever of claim 10, comprising one or more waveguides.

18. A photonic system comprising:
a photonic integrated circuit (PIC) chip comprising the cantilever of claim 10.
